(19) United States
(12) Patent Application Publication
(10) Pub. No.: US 2007/0069222 A1
(43) Pub. Date: Mar. 29, 2007

(54) Gallium nitride based semiconductor light emitting diode and method of manufacturing the same

(75) Inventors: Kun Yoo Ko, Hwaseong (KR); Bang Won Oh, Seongnam (KR); Bok Ki Min, Suwon (KR); Hyung Jin Park, Suwon (KR); Seok Min Hwang, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/524,198

(22) Filed: Sep. 21, 2006

(30) Foreign Application Priority Data
Sep. 26, 2005 (KR) 10-2005-0089199

(51) Int. Cl. H01L 33/00

(52) U.S. Cl. 257/86

(57) ABSTRACT

A GaN based LED and a method of manufacturing the same are provided. The GaN based semiconductor LED can have an improved heat dissipation capability of a sapphire substrate, thereby preventing device characteristic from being degraded by heat and improving the luminous efficiency of the device. In the GaN based LED, a sapphire substrate has at least one groove formed in a lower portion thereof. A thermally conductive layer having higher thermal conductivity than the sapphire substrate is formed on a bottom surface of the sapphire substrate to fill the groove. An n-type nitride semiconductor layer is formed on the sapphire substrate, and an active layer and a p-type nitride semiconductor layer are sequentially formed on a predetermined portion of the n-type nitride semiconductor layer. A p-electrode and an n-electrode are formed on the p-type nitride semiconductor layer and the n-type nitride semiconductor layer, respectively.

### CROSS-REFERENCE TO RELATED APPLICATIONS

This application claims the benefit of Korean Patent Application No. 2005-89199 filed with the Korean Industrial Property Office on Sep. 26, 2005, the disclosure of which is incorporated herein by reference.

### BACKGROUND OF THE INVENTION

1. Field of the Invention

The present invention relates to a gallium nitride based semiconductor light emitting diode (LED) and a method of manufacturing the same. The gallium nitride based semiconductor LED can improve a heat dissipation capability of a sapphire substrate, thereby preventing device characteristic from being degraded by heat and improving the luminous efficiency of the device.

2. Description of the Related Art

Because group III-V nitride semiconductors such as GaN have excellent physical and chemical properties, they are considered as essential materials of light emitting devices, for example, light emitting diodes (LEDs) or laser diode (LDs). The LEDs or LDs formed of the group III-V nitride semiconductors are widely used in the light emitting devices for obtaining blue or green light. The light emitting devices are applied to light sources of various products, such as household appliances, electronic display boards, and lighting devices. Generally, the group III-V nitride semiconductors are comprised of gallium nitride (GaN) based materials having an empirical formula of In_{X}Al_{Y}Ga_{1-X-Y}N (0≦X, 0≦Y, X+Y≦1).

Because the GaN based semiconductor LEDs using GaN based materials cannot form GaN bulk single crystal, a substrate suitable for the growth of GaN crystal should be used. A sapphire substrate is widely used.

A GaN based semiconductor LED according to the related art will be described below with reference to FIG. 1.

FIG. 1 is a sectional view of a GaN based semiconductor LED according to the related art.

Referring to FIG. 1, the GaN based semiconductor LED 100 includes an n-type nitride semiconductor layer 102, an active layer 103, and a p-type nitride semiconductor layer 104, which are sequentially formed on a sapphire substrate 101. The sapphire substrate 101 is provided for growing a GaN based semiconductor material. A portion of the p-type nitride semiconductor layer 104 and a portion of the active layer 103 are removed by a mesa etching process, so that a predetermined upper portion of the n-type nitride semiconductor layer 102 is exposed.

The n-type nitride semiconductor layer 102, the p-type nitride semiconductor layer 104, and the active layer 103 may be formed of semiconductor materials having an empirical formula of In_{X}Al_{Y}Ga_{1-X-Y}N (0≦X, 0≦Y, X+Y≦1). More specifically, the n-type nitride semiconductor layer 102 may be a GaN layer or GaN/AlGaN layer doped with n-type impurities. The p-type nitride semiconductor layer 104 may be a GaN layer or GaN/AlGaN layer doped with p-type impurities. The active layer 103 may be a GaN/InGaN layer having a multi quantum well structure.

A positive electrode (p-electrode) 106 is formed on a portion of the p-type nitride semiconductor layer 104, which is not etched by the mesa etching process. A negative electrode (n-electrode) 107 is formed on a portion of the n-type nitride semiconductor layer 102, which is exposed by the mesa etching process. The p-electrode 106 and the n-electrode 107 may be formed of metal materials, such as Au or Cr/Au.

Prior to the formation of the p-electrode 106, a transparent electrode 105 may be formed on the p-type nitride semiconductor layer 104 so as to increase a current injection area and form an ohmic contact. The transparent electrode 105 is generally formed of indium tin oxide (ITO).

A method of manufacturing the GaN based semiconductor LED according to the related art will be described below.

An n-type nitride semiconductor layer 102, an active layer 103, and a p-type nitride semiconductor layer 104 are sequentially grown on a sapphire substrate 101. The p-type nitride semiconductor layer 104, the active layer 103, and the n-type nitride semiconductor layer 102 are partially mesa-etched to expose a portion of the n-type nitride semiconductor layer 102. Then, a transparent electrode 105 is formed on the p-type nitride semiconductor layer 104. The transparent electrode 105 may be formed of ITO. A p-electrode 106 is formed on the transparent electrode 105, and an n-electrode 107 is formed on the n-type nitride semiconductor layer 102. The p-electrode 106 and the n-electrode 107 may be formed of a metal, such as Au or Au/Cr.

However, the GaN based semiconductor LED according to the related art has a problem in that heat generated from the LED 100 is not quickly dissipated through the sapphire substrate 101 to the outside because the sapphire substrate 101 has high thermal resistance. Therefore, junction temperature increases and the device characteristic is degraded. This problem is more serious in high-power LEDs that are used in medium or large sized LCD backlight or lamp. Thus, the increase of the luminous efficiency is continuously required.

### SUMMARY OF THE INVENTION

An advantage of the present invention is that it provides a GaN based semiconductor LED that can improved a heat dissipation capability of a sapphire substrate. Therefore, the characteristic degradation of the device due to heat can be prevented and the luminous efficiency of the device can be increased. In addition, the present invention provides a method of manufacturing the GaN based semiconductor LED.

Additional aspect and advantages of the present general inventive concept will be set forth in the description which follows and, in part, will be obvious from the description, or may be learned by practice of the general inventive concept.

According to an aspect of the invention, a GaN based semiconductor LED includes: a sapphire substrate having at least one groove formed in a lower portion thereof; a thermally conductive layer formed on a bottom surface of the sapphire substrate to fill the groove, the thermally conductive layer having higher thermal conductivity than the sapphire substrate; an n-type nitride semiconductor layer formed on the sapphire substrate; an active layer and a p-type nitride semiconductor layer sequentially formed on a predetermined portion of the n-type nitride semiconductor layer; and a p-electrode and an n-electrode formed on the p-type nitride semiconductor layer and the n-type nitride semiconductor layer, respectively.

According to another aspect of the present invention, the GaN based semiconductor LED further includes a reflective layer formed between the sapphire substrate and the thermally conductive layer. The reflective layer has higher reflectivity than the sapphire substrate.

According to a further aspect of the present invention, the thermally conductive layer is formed of at least one material selected from the group consisting of Ag, Cu, Pt, SiC, AlN, solder paste, and thermally conductive polymer.

According to a still further aspect of the present invention, the thermally conductive layer is formed using at least one process selected from the group consisting of e-beam deposition, sputtering, thermal deposition, chemical vapor deposition, printing, and spin coating.

According to a still further aspect of the present invention, a GaN based semiconductor LED includes: a sapphire substrate having at least one groove at a lower portion; a reflective layer formed on a bottom surface of the sapphire substrate to fill the groove, the reflective layer having higher reflectivity than the sapphire substrate; an n-type nitride semiconductor layer formed on the sapphire substrate; an active layer and a p-type nitride semiconductor layer sequentially formed on a predetermined portion of the n-type nitride semiconductor layer; and a p-electrode and an n-electrode formed on the p-type nitride semiconductor layer and the n-type nitride semiconductor layer, respectively.

According to a still further aspect of the present invention, the reflective layer is formed of at least one material selected from the group consisting of Ag, Al, Rh, Au, Cr, and Pt.

According to a still further aspect of the present invention, the reflective layer is formed using at least one process selected from e-beam deposition, sputtering, thermal deposition, chemical vapor deposition, printing, spin coating.

According to a still further aspect of the present invention, the groove is formed using femto-second laser.

According to a still further aspect of the present invention, the groove has a diameter of 5 μm to 900 μm.

According to a still further aspect of the present invention, the groove is formed to have a depth of 5 μm from the bottom surface of the sapphire substrate, or up to an interface between the sapphire substrate and the n-type nitride semiconductor layer.

According to a still further aspect of the present invention, when the groove is provided in plurality, the plurality of grooves are spaced apart from one other at a predetermined distance.

According to a still further aspect of the present invention, a method of manufacturing a GaN based semiconductor LED includes: forming an n-type nitride semiconductor layer, an active layer, a p-type nitride semiconductor layer on a sapphire substrate; partially mesa-etching the p-type nitride semiconductor layer, the active layer, and the n-type nitride semiconductor layer to expose a portion of the n-type nitride semiconductor layer; forming a p-electrode and an n-electrode on the p-type nitride semiconductor layer and the n-type nitride semiconductor layer, respectively; forming at least one groove in a lower portion of the sapphire substrate; and forming a thermally conductive layer on a bottom surface of the sapphire substrate to fill the groove, the thermally conductive layer having higher thermal conductivity than the sapphire substrate.

According to a still further aspect of the present invention, the method further includes forming a reflective layer along the bottom surface of the sapphire substrate with the groove, the reflective layer having higher reflectivity than the sapphire substrate.

According to a still further aspect of the present invention, the thermally conductive layer is formed of at least one material selected from the group consisting of Ag, Cu, Pt, SiC, AlN, solder paste, and thermally conductive polymer.

According to a still further aspect of the present invention, the thermally conductive layer is formed using at least one process selected from the group consisting of e-beam deposition, sputtering, thermal deposition, chemical vapor deposition, printing, and spin coating.

According to a still further aspect of the present invention, a method of manufacturing a GaN based semiconductor LED includes: forming an n-type nitride semiconductor layer, an active layer, a p-type nitride semiconductor layer on a sapphire substrate; partially mesa-etching the p-type nitride semiconductor layer, the active layer, and the n-type nitride semiconductor layer to expose a portion of the n-type nitride semiconductor layer; forming a p-electrode and an n-electrode on the p-type nitride semiconductor layer and the n-type nitride semiconductor layer, respectively; forming at least one groove in a lower portion of the sapphire substrate; and forming a reflective layer on a bottom surface of the sapphire substrate to fill the groove, the reflective layer having higher reflectivity than the sapphire substrate.

According to a still further aspect of the present invention, the reflective layer is formed of at least one material selected from the group consisting of Ag, Al, Rh, Au, Cr, and Pt.

According to a still further aspect of the present invention, the reflective layer is formed using at least one process selected from the group consisting of e-beam deposition, sputtering, thermal deposition, chemical vapor deposition, printing, and spin coating.

According to a still further aspect of the present invention, the groove is formed using femto-second laser.

According to a still further aspect of the present invention, the groove is formed to have a diameter of 5 μm to 900 μm.

According to a still further aspect of the present invention, the groove is formed to have a depth of 5 μm from the bottom surface of the sapphire substrate, or up to an interface between the sapphire substrate and the n-type nitride semiconductor layer.

According to a still further aspect of the present invention, when the groove is provided in plurality, the plurality of grooves are spaced apart from one other at a predetermined distance.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a sectional view of a gallium nitride based semiconductor LED according to the related art;

FIGS. 2 and 3 are sectional views of a gallium nitride based semiconductor LED according to a first embodiment of the present invention;

FIGS. 4A to 4E are sectional views illustrating a method of manufacturing the gallium nitride based semiconductor LED according to the first embodiment of the present invention;

FIG. 5 is a sectional view of a gallium nitride based semiconductor LED according to a second embodiment of the present invention;

FIG. 6 is a sectional view of a gallium nitride based semiconductor LED according to a third embodiment of the present invention; and

FIGS. 7A to 7C are sectional views illustrating a method of manufacturing a gallium nitride based semiconductor LED according to the third embodiment of the present invention.

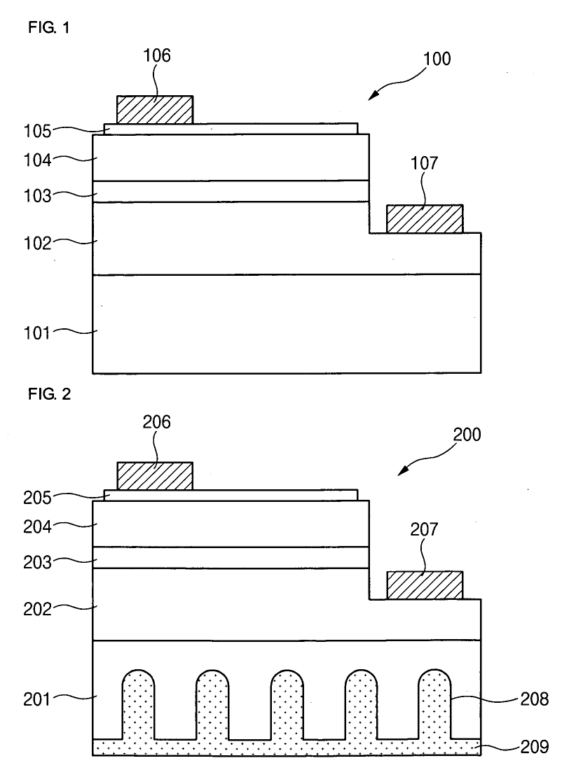

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

### Embodiment 1

Structure of GaN Based Semiconductor LED

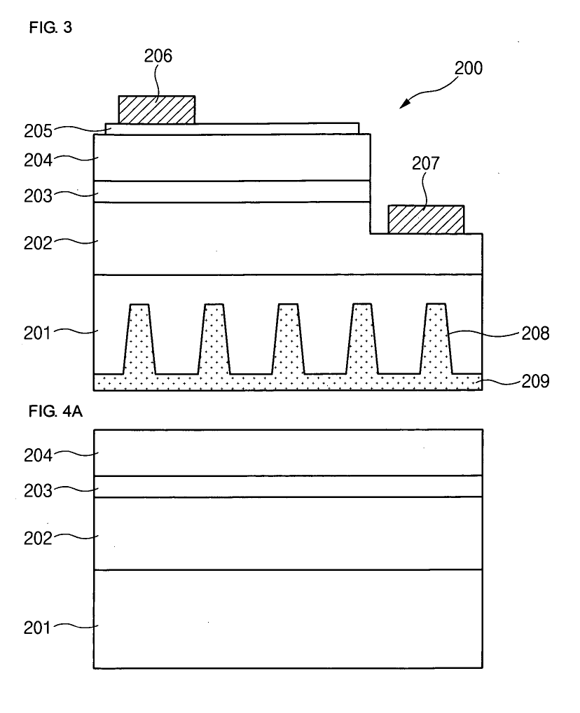

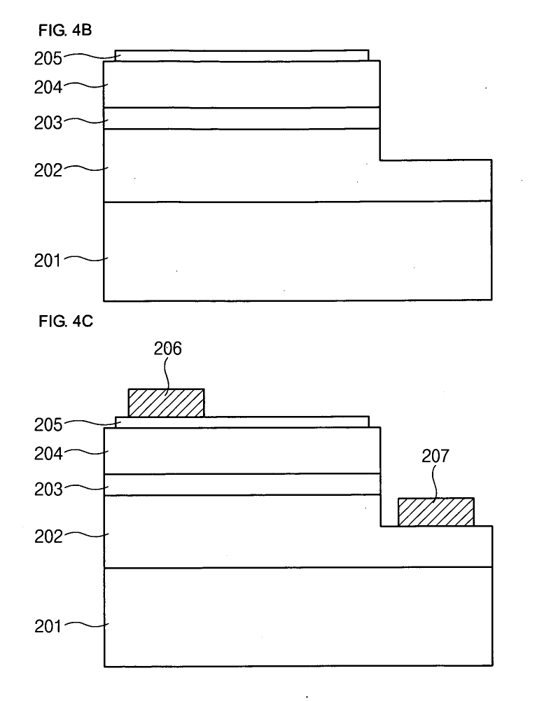

Hereinafter, a GaN based semiconductor LED according to a first embodiment of the present invention will be described in detail with reference to FIGS. 2 and 3.

FIGS. 2 and 3 are sectional views of a GaN based semiconductor LED according to a first embodiment of the present invention.

Referring to FIG. 2, the GaN based semiconductor LED 200 includes an n-type nitride semiconductor layer 202, an active layer 203, and a p-type nitride semiconductor layer 204, which are sequentially formed on a sapphire substrate 201. The sapphire substrate 201 is provided for growing a GaN based semiconductor material. A portion of the p-type nitride semiconductor layer 204 and a portion of the active layer 203 are removed by a mesa etching process, so that a predetermined upper portion of the n-type nitride semiconductor layer 202 is exposed.

The n-type nitride semiconductor layer 202, the p-type nitride semiconductor layer 204, and the active layer 203 may be formed of semiconductor materials having an empirical formula of In_{X}Al_{Y}Ga_{1-X-Y}N (0≦X, 0≦Y, X+Y≦1). More specifically, the n-type nitride semiconductor layer 202 may be a GaN layer or GaN/AlGaN layer doped with n-type impurities. The p-type nitride semiconductor layer 204 may be a GaN layer or GaN/AlGaN layer doped with p-type impurities. The active layer 203 may be a GaN/InGaN layer having a multi quantum well structure.

A p-electrode 206 is formed on a portion of the p-type nitride semiconductor layer 204, which is not etched by the mesa etching process. An n-electrode 207 is formed on a portion of the n-type nitride semiconductor layer 202, which is exposed by the mesa etching process. The p-electrode 206 and the n-electrode 207 may be formed of metal materials, such as Au or Cr/Au. Prior to the formation of the p-electrode 206, a transparent electrode 205 may be formed on the p-type nitride semiconductor layer 204. The transparent electrode 205 may be formed of ITO.

In this embodiment, at least one groove 208 is formed in a lower portion of the sapphire substrate 201. In order to fill the groove 208, a thermally conductive layer 209 having higher thermal conductivity than the sapphire substrate 201 is formed on a bottom surface of the sapphire substrate 201. The thermally conductive layer 209 filling the groove 208 quickly dissipates heat generated within the LED 200 through the sapphire substrate 201 to the outside. Therefore, the heat dissipation capability of the sapphire substrate 201 can be improved, thereby preventing the device characteristic from being degraded by the heat.

The groove 208 may be formed using inductive coupled plasma (ICP), reactive ion etching (RIE), or femto-second laser. Meanwhile, it is most preferable that the groove 208 be formed using the femto-second laser.

The femto-second laser has a pulse discharge time of 10⁻¹³-10⁻¹⁵ second, which is less than 1 pico-second. Generally, when ultra-short pulse laser beam such as the femto-second laser is emitted to a product, multi photon phenomenon occurs in the lattice of material. The incident pulse is shorter than the time taken for the photon to transfer heat to the adjacent lattice while atoms are excited. Therefore, it is possible to prevent the degradation of processing precision and changes in physical and chemical properties of materials due to the thermal diffusion while the product is processed. Consequently, the processing can be performed with high precision. In addition, when the processing is performed using the femto-second laser, by-products such as particles are not almost generated. Therefore, a particle removing step such as an ultrasonic cleaning process is unnecessary.

When the groove 208 is formed using the femto-second laser, the groove 208 may have a cylindrical section of FIG. 2A or a trapezoidal section of FIG. 3 according to the processing method. The section of the groove 208 is not limited to the cylindrical or trapezoidal shape, but may have various shapes without departing from the sprit and scope of the present invention.

It is preferable that the diameter of the groove 208 is in a range from 5 μm to 900 μm. When the diameter of the groove 208 is less than 5 μm, it is impossible to sufficiently obtain the heat dissipation capability of the sapphire substrate 201. Considering the size of the general sapphire substrate 201, it is difficult to form the groove 208 having the diameter of more than 900 μm. Therefore, it is preferable that the groove 208 is formed to have the diameter ranging from 5 μm to 900 μm.

In addition, it is preferable that the groove 208 is formed to have the depth of 5 μm from the bottom surface of the sapphire substrate 201, or up to the interface of the n-type nitride semiconductor layer 202. If the depth of the groove 208 is less than 5 μm, the heat generated within the GaN based semiconductor LED 200 may be difficult to reach the thermally conducive layer 209 formed in the groove 208 through the sapphire substrate 201. Moreover, when a plurality of grooves 208 are formed in the sapphire substrate 201 as illustrated in FIG. 2, it is preferable that they are spaced apart from one another at a predetermined distance.

The thermally conductive layer 209 having higher thermal conductivity than the sapphire substrate 201 may be formed of at least one material selected from the group consisting of Ag, Cu, Pt, SiC, AlN, solder paste, and thermally conductive polymer. In addition, the thermally conductive layer 209 may be formed using at least one process selected from the group consisting of e-beam deposition, sputtering, thermal deposition, chemical vapor deposition (CVD), printing, and spin coating.

Method of Manufacturing GaN Based Semiconductor LED

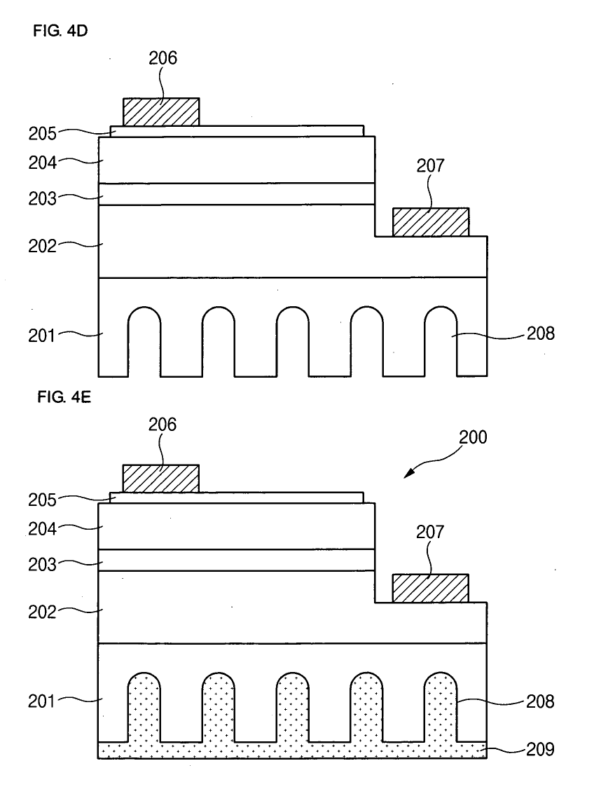

Hereinafter, a method of manufacturing the GaN based semiconductor LED according to the first embodiment of the present invention will be described in detail with reference to FIGS. 4A to 4E.

FIGS. 4A to 4E are sectional views illustrating a method of manufacturing the GaN based semiconductor LED according to the first embodiment of the present invention.

Referring to FIG. 4A, an n-type nitride semiconductor layer 202, an active layer 203, and a p-type nitride semiconductor layer 204 are sequentially formed on a sapphire substrate 201 for growing GaN based semiconductor materials.

The n-type nitride semiconductor layer 202, the p-type nitride semiconductor layer 204, and the active layer 203 may be formed of semiconductor materials having an empirical formula of In_{X}Al_{Y}Ga_{1-X-Y}N (0≦X, 0≦Y, X+Y≦1). More specifically, the n-type nitride semiconductor layer 202 may be a GaN layer or GaN/AlGaN layer doped with n-type impurities. Examples of the n-type impurities include Si, Ge, and Sn. Among them, Si is widely used. The p-type nitride semiconductor layer 204 may be formed of a GaN layer or GaN/AlGaN layer doped with p-type impurities. Examples of the p-type impurities include Mg, Zn, and Be. Among them, Mg is widely used. The active layer 203 may be formed of a GaN/InGaN layer having a multi quantum well structure.

The n-type nitride semiconductor layer 202, the p-type nitride semiconductor layer 204, and the active layer 203 may be formed using metal organic chemical vapor deposition (MOCVD).

Referring to FIG. 4B, the p-type nitride semiconductor layer 204, the active layer 203, and the n-type nitride semiconductor layer 202 are partially mesa-etched to expose a portion of the n-type nitride semiconductor layer 202. Then, a transparent electrode 205 is formed on a portion of the p-type nitride semiconductor layer 204, which is not etched by the mesa etching process. The transparent electrode 205 may be formed of ITO.

Referring to FIG. 4C, a p-electrode 206 is formed on the transparent electrode 205, and an n-electrode 207 is formed on a portion of the n-type nitride semiconductor layer 202, which is exposed by the mesa etching process. The p-electrode 206 and the n-electrode 207 may be formed of metal, such as Au or Au/Cr.

Referring to FIG. 4D, at least one groove 208 is formed in a lower portion of the sapphire substrate 201. The groove 208 may be formed using femto-second laser. The groove 208 may be formed to have various sections, including a cylindrical section as illustrated in FIG. 4D, according to the processing methods. It is preferable that the diameter of the groove 208 is in a range from 5 μm to 900 μm. In addition, it is preferable that the groove 208 is formed to have the depth of 5 μm from the bottom surface of the sapphire substrate 201, or up to the interface between the sapphire substrate 201 and the n-type nitride semiconductor layer 202. Moreover, when a plurality of grooves 208 are formed in the sapphire substrate 201, it is preferable that they are spaced apart from one another by a predetermined distance.

Referring to FIG. 4E, a thermally conductive layer 209 having higher thermal conductivity than the sapphire substrate 201 is formed on a bottom surface of the sapphire substrate 201 to fill the groove 208. The thermally conductive layer 209 may be formed of at least one material selected from the group consisting of Ag, Cu, Pt, SiC, AlN, solder paste, and thermally conductive polymer. In addition, the thermally conductive layer 209 may be formed using at least one process selected from the group consisting of e-beam deposition, sputtering, thermal deposition, chemical vapor deposition (CVD), printing, and spin coating. Because of the thermally conductive layer 209 filling the groove 208, the heat generated within the LED 200 can be quickly dissipated through the sapphire substrate 201 to the outside.

According to the first embodiment of the present invention, the heat dissipation capability of the sapphire substrate 201 can be improved by forming the thermally conductive layer 209 in the groove 208, thereby preventing the device characteristic from being degraded by the heat.

### Embodiment 2

Structure of GaN Based Semiconductor LED

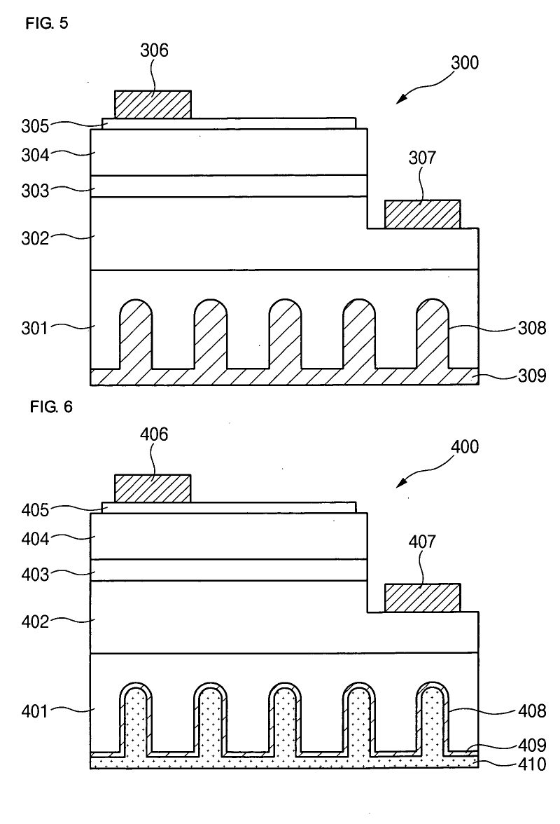

Hereinafter, a GaN based semiconductor LED according to a second embodiment of the present invention will be described in detail with reference to FIG. 5. The descriptions of the same parts as the first embodiment of the present invention will be omitted for conciseness.

FIG. 5 is a sectional view of a GaN based semiconductor LED according to a second embodiment of the present invention.

Referring to FIG. 5, the GaN based semiconductor LED 300 according to the second embodiment of the present invention has the same structure as the GaN based semiconductor LED 200 according to the first embodiment of the present invention, except that a reflective layer 309 instead of the thermally conductive layer 209 is formed in a lower portion of a sapphire substrate 301 so as to fill a groove 309.

That is, the GaN based semiconductor LED 300 according to the second embodiment of the present invention includes an n-type nitride semiconductor layer 302, an active layer 303, and a p-type nitride semiconductor layer 304, which are sequentially formed on a sapphire substrate 301. A portion of the p-type nitride semiconductor layer 304 and a portion of the active layer 303 are removed by a mesa etching process, so that a predetermined upper portion of the n-type nitride semiconductor layer 302 is exposed. A transparent electrode 305 and a p-electrode 306 are sequentially formed on a portion of the p-type nitride semiconductor layer 304, which is not etched by the mesa etching process. An n-electrode 307 is formed on a portion of the n-type nitride semiconductor layer 302, which is exposed by the etching process.

In addition, at least one groove 308 is formed in a lower portion of the sapphire substrate 301. In order to fill the groove 308, a reflective layer 309 having higher reflectivity than the sapphire substrate 301 is formed on a bottom surface of the sapphire substrate 301.

The reflective layer 309 may be formed of at least one material selected from the group consisting of Ag, Al, Rh, Au, Cr and Pt. Furthermore, the reflective layer 309 may be formed using at least one process selected from the group consisting of e-beam deposition, sputtering, thermal deposition, chemical vapor deposition (CVD), printing, and spin coating. Light directed from the active layer 303 to the sapphire substrate 301 is reflected by the reflective layer 309, thereby improving the luminous efficiency of the LED 300.

Method of Manufacturing GaN Based Semiconductor LED

Hereinafter, a method of manufacturing the GaN based semiconductor LED according to the second embodiment of the present invention will be described in detail with reference to FIG. 5.

The manufacturing method according to the second embodiment of the present invention is identical to the manufacturing method according to the first embodiment of the present invention until the process of forming the groove 308 in the lower portion of the sapphire substrate 301.

After forming the groove 308 in the lower portion of the sapphire substrate 301, a reflective layer 309 having higher reflectivity than the sapphire substrate 301 is formed on the bottom surface of the sapphire substrate 301 to fill the groove 308. It is preferable that the reflective layer 309 is formed of at least one material selected from the group consisting of Ag, Al, Rh, Au, Cr and Pt. Furthermore, the reflective layer 309 may be formed using at least one process selected from the group consisting of e-beam deposition, sputtering, thermal deposition, chemical vapor deposition (CVD), printing, and spin coating.

According to the second embodiment of the present invention, the reflective layer 309 is formed on the groove 308 formed in the lower portion of the sapphire substrate 301 so as to reflect light directed from the active layer 303 to the sapphire substrate 301, thereby improving the luminous efficiency of the LED 300.

### Embodiment 3

Structure of GaN Based Semiconductor LED

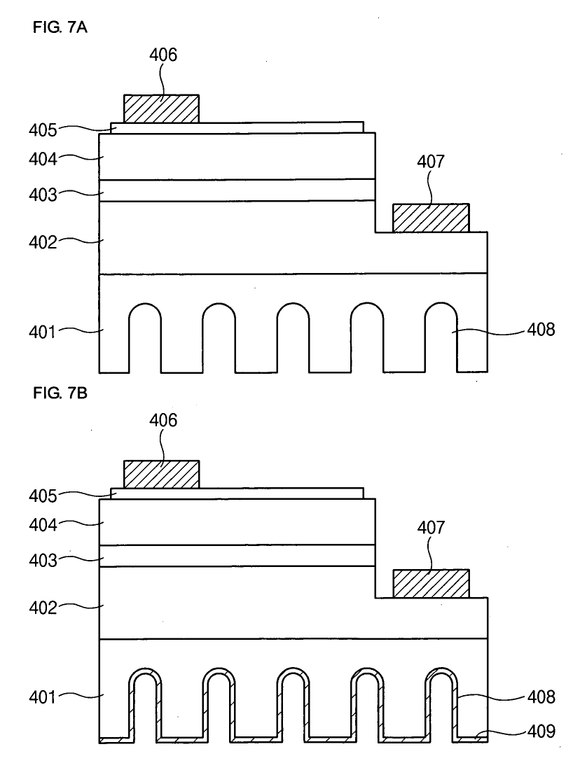

Hereinafter, a GaN based semiconductor LED according to the third embodiment of the present invention will be described in detail with reference to FIG. 6. The descriptions of the same parts as the first embodiment of the present invention will be omitted for conciseness.

FIG. 6 is a sectional view of a GaN based semiconductor LED according to a third embodiment of the present invention.

Referring to FIG. 6, the GaN based semiconductor LED 400 according to the third embodiment of the present invention has the same structure as the GaN based semiconductor LED 200 according to the first embodiment of the present invention, except that a reflective layer 409 having higher reflectivity than a sapphire substrate 401 is further formed between the sapphire substrate 401 with a groove 408 and a thermally conductive layer 410.

That is, the GaN based semiconductor LED 400 according to the third embodiment of the present invention includes both a reflective layer 409 and a thermally conductive layer 410. The reflective layer 409 reflects light directed from the active layer 403 to the sapphire substrate 401, thereby improving the luminous efficiency of the LED, and the thermally conductive layer 410 can improve the heat dissipation capability of the sapphire substrate 401. Therefore, the GaN based semiconductor LED 400 can simultaneously obtain the effects of the first and second embodiments of the present invention.

In FIG. 6, reference numerals 402, 404, 405, 406 and 407 represent an n-type nitride semiconductor layer, a p-type nitride semiconductor layer, a transparent electrode, a p-electrode, and an n-electrode, respectively.

Method of Manufacturing GaN Based Semiconductor LED

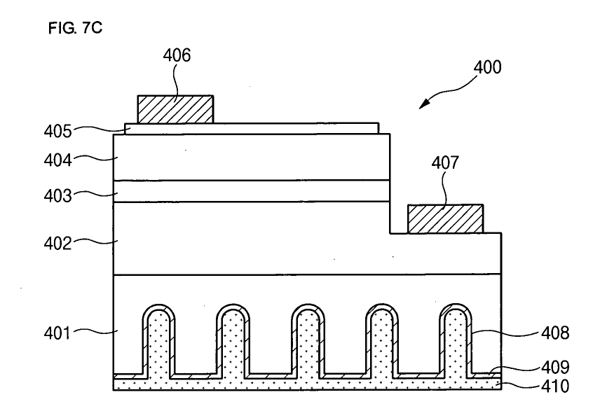

Hereinafter, a method of manufacturing the GaN based semiconductor LED according to the third embodiment of the present invention will be described in detail with reference to FIGS. 7A to 7C.

FIGS. 7A to 7C are sectional views illustrating a method of manufacturing the GaN based semiconductor LED according to the third embodiment of the present invention.

Referring to FIG. 7A, the manufacturing method according to the third embodiment of the present invention is identical to the manufacturing method according to the first embodiment of the present invention until the process of forming the groove 408 in the lower portion of the sapphire substrate 401.

Referring to FIG. 7B, a reflective layer 409 having higher reflectivity than the sapphire substrate 401 is formed along the bottom surface of the sapphire substrate 401 with the groove 408.

Referring to FIG. 7C, a thermally conductive layer 410 having higher thermal conductivity than the sapphire substrate 401 is formed on the reflective layer 409 to fill the groove 408.

According to the third embodiment of the present invention, the reflective layer 409 and the thermally conductive layer 410 are sequentially formed in the groove 408 that is formed in the lower portion of the sapphire substrate 401. Therefore, light directed from the active layer 403 to the sapphire substrate 401 is reflected, thereby improving the luminous efficiency of the LED. Moreover, the heat dissipation capacity of the sapphire substrate 401 is improved, thereby preventing the device characteristic from being degraded by the heat.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A gallium nitride (GaN) based semiconductor light emitting diode (LED) comprising:
a sapphire substrate having at least one groove formed in a lower portion thereof;
a thermally conductive layer formed on a bottom surface of the sapphire substrate to fill the groove, the thermally conductive layer having higher thermal conductivity than the sapphire substrate;
an n-type nitride semiconductor layer formed on the sapphire substrate;
an active layer and a p-type nitride semiconductor layer sequentially formed on a predetermined portion of the n-type nitride semiconductor layer; and
a p-electrode and an n-electrode formed on the p-type nitride semiconductor layer and the n-type nitride semiconductor layer, respectively.

2. A GaN based semiconductor LED comprising:
a sapphire substrate having at least one groove formed in a lower portion thereof;
a reflective layer formed on a bottom surface of the sapphire substrate to fill the groove, the reflective layer having higher reflectivity than the sapphire substrate;
an n-type nitride semiconductor layer formed on the sapphire substrate;
an active layer and a p-type nitride semiconductor layer sequentially formed on a predetermined portion of the n-type nitride semiconductor layer; and
a p-electrode and an n-electrode formed on the p-type nitride semiconductor layer and the n-type nitride semiconductor layer, respectively.

3. The GaN based semiconductor LED according to claim 1, further comprising:
a reflective layer formed between the sapphire substrate and the thermally conductive layer, the reflective layer having higher reflectivity than the sapphire substrate.

4. The GaN based semiconductor LED according to claim 1,
wherein the thermally conductive layer is formed of at least one material selected from the group consisting of Ag, Cu, Pt, SiC, AIN, solder paste, and thermally conductive polymer.

5. The GaN based semiconductor LED according to claim 1,
wherein the thermally conductive layer is formed using at least one process selected from the group consisting of e-beam deposition, sputtering, thermal deposition, chemical vapor deposition, printing, and spin coating.

6. The GaN based semiconductor LED according to claim 2,
wherein the reflective layer is formed of at least one material selected from the group consisting of Ag, Al, Rh, Au, Cr, and Pt.

7. The GaN based semiconductor LED according to claim 2,
wherein the reflective layer is formed using at least one process selected from e-beam deposition, sputtering, thermal deposition, chemical vapor deposition, printing, spin coating.

8. The GaN based semiconductor LED according to claim 1,
wherein the groove is formed using femto-second laser.

9. The GaN based semiconductor LED according to claim 1,
wherein the groove has a diameter of 5 μm to 900 μm.

10. The GaN based semiconductor LED according to claim 1,
wherein the groove is formed to have a depth of 5 μm from the bottom surface of the sapphire substrate, or up to an interface between the sapphire substrate and the n-type nitride semiconductor layer.

11. The GaN based semiconductor LED according to claim 1,
wherein when the groove is provided in plurality, the plurality of grooves are spaced apart from one other at a predetermined distance.

12. A method of manufacturing a GaN based semiconductor LED, comprising:
forming an n-type nitride semiconductor layer, an active layer, a p-type nitride semiconductor layer on a sapphire substrate;
partially mesa-etching the p-type nitride semiconductor layer, the active layer, and the n-type nitride semiconductor layer to expose a portion of the n-type nitride semiconductor layer;
forming a p-electrode and an n-electrode on the p-type nitride semiconductor layer and the n-type nitride semiconductor layer, respectively;
forming at least one groove in a lower portion of the sapphire substrate; and
forming a thermally conductive layer on a bottom surface of the sapphire substrate to fill the groove, the thermally conductive layer having higher thermal conductivity than the sapphire substrate.

13. A method of manufacturing a GaN based semiconductor LED, comprising:
forming an n-type nitride semiconductor layer, an active layer, a p-type nitride semiconductor layer on a sapphire substrate;
partially mesa-etching the p-type nitride semiconductor layer, the active layer, and the n-type nitride semiconductor layer to expose a portion of the n-type nitride semiconductor layer;
forming a p-electrode and an n-electrode on the p-type nitride semiconductor layer and the n-type nitride semiconductor layer, respectively;
forming at least one groove in a lower portion of the sapphire substrate; and
forming a reflective layer on a bottom surface of the sapphire substrate to fill the groove, the reflective layer having higher reflectivity than the sapphire substrate.

14. The method according to claim 12, further comprising,
after forming the groove, forming a reflective layer along the bottom surface of the sapphire substrate with the groove, the reflective layer having higher reflectivity than the sapphire substrate.

15. The method according to claim 12,
wherein the thermally conductive layer is formed of at least one material selected from the group consisting of Ag, Cu, Pt, SiC, AIN, solder paste, and thermally conductive polymer.

16. The method according to claim 12,
wherein the thermally conductive layer is formed using at least one process selected from the group consisting of e-beam deposition, sputtering, thermal deposition, chemical vapor deposition, printing, and spin coating.

17. The method according to claim 13,
wherein the reflective layer is formed of at least one material selected from the group consisting of Ag, Al, Rh, Au, Cr, and Pt.

18. The method according to claim 13,
wherein the reflective layer is formed using at least one process selected from the group consisting of e-beam deposition, sputtering, thermal deposition, chemical vapor deposition, printing, and spin coating.

19. The method according to claim 12,
wherein the groove is formed using femto-second laser.

20. The method according to claim 12,
wherein the groove is formed to have a diameter of 5 μm to 900 μm.

21. The method according to claim 12,
wherein the groove is formed to have a depth of 5 μm from the bottom surface of the sapphire substrate, or up to an interface between the sapphire substrate and the n-type nitride semiconductor layer.

22. The method according to claim 12,
wherein when the groove is provided in plurality, the plurality of grooves are spaced apart from one other at a predetermined distance.
